(19) United States
(12) Patent Application Publication
(10) Pub. No.: US 2023/0268395 A1
(43) Pub. Date: Aug. 24, 2023

(54) SEMICONDUCTOR DEVICES

(71) Applicant: Samsung Electronics Co., Ltd., Suwon-si (KR)

(72) Inventors: Jinbum KIM, Suwon-si (KR); Sujin JUNG, Hwaseong-si (KR); Gyeom KIM, Hwaseong-si (KR); Dahye KIM, Seoul (KR); Ingyu JANG, Seoul (KR); Kyungbin CHUN, Suwon-si (KR)

(73) Assignee: Samsung Electronics Co., Ltd., Suwon-si (KR)

(21) Appl. No.: 18/062,713

(22) Filed: Dec. 7, 2022

(30) Foreign Application Priority Data
Feb. 22, 2022 (KR) 10-2022-0023056

(51) Int. Cl. H01L 29/08; H01L 29/06; H01L 29/423; H01L 29/775; H01L 21/764; H01L 29/66

(52) U.S. Cl. CPC H01L 29/0847; H01L 29/0673; H01L 29/42392; H01L 29/775; H01L 21/764; H01L 29/66545; H01L 29/66553; H01L 29/66742; H01L 29/66439

(57) ABSTRACT

A semiconductor device includes; a gate structure intersecting an active region, and a plurality of channel layers, extending on the substrate in a second direction, and surrounding the plurality of channel layers; a source/drain region contacting the plurality of channel layers on at least one side of the gate structure and including a first semiconductor material with first impurities having a first conductivity type; and a lower structure in contact with the active region and below the source/drain region. The lower structure includes a first layer disposed on the active region and including an insulating material; a second layer disposed on the first layer and including a second semiconductor material; with an air gap defined by the first layer and the second layer, wherein the second semiconductor material of the second layer has no conductivity type or has a second conductivity type different from the first conductivity type.

### CROSS-REFERENCE TO RELATED APPLICATION(S)

This application claims benefit of priority to Korean Patent Application No. 10-2022-0023056 filed on Feb. 22, 2022 in the Korean Intellectual Property Office, the disclosure of which is incorporated herein by reference in its entirety.

### BACKGROUND

Various example embodiments disclosure relate to a semiconductor device.

As demand for high performance, high speed, and/or multifunctionality in a semiconductor device have increased, integration density of a semiconductor device has increased. In manufacturing a semiconductor device having a fine pattern corresponding to the trend for high integration density of a semiconductor device, it has been necessary or desirable to implement patterns having a fine width or a fine spacing. Also, to overcome or partially overcome limitations of operational properties due to the reduction of a size of a planar metal oxide semiconductor FET (MOSFET), there have been attempts to develop a semiconductor device including a FinFET having a three-dimensional channel structure.

### SUMMARY

Some example embodiments vide a semiconductor device having improved electrical properties.

According to some example embodiments, a semiconductor device includes an active region extending on a substrate in a first direction; a plurality of channel layers arranged vertically and spaced apart from each other on the active region; a gate structure intersecting the active region and the plurality of channel layers, extending on the substrate in a second direction, and surrounding the plurality of channel layers; a source/drain region contacting the plurality of channel layers on at least one side of the gate structure and including a first semiconductor material having first impurities with a first conductivity type; and a lower structure in contact with the active region and disposed below the source/drain region. The lower structure includes a first layer on the active region and including an insulating material; a second layer on the first layer and including a second semiconductor material; and the first layer and the second layer defining an air gap. The second semiconductor material of the second layer has no conductivity type or includes impurities having a second conductivity type different from the first conductivity type.

According to some example embodiments, a semiconductor device includes an active region extending on a substrate in a first direction; a plurality of channel layers arranged vertically and spaced apart from each other on the active region; a gate structure intersecting the active region and the plurality of channel layers, extending on the substrate in a second direction, and surrounding the plurality of channel layers; a source/drain region contacting the plurality of channel layers on at least one side of the gate structure; and a lower structure in contact with the active region, below the source/drain region, and including a first layer and a second layer and defining air gap, the first layer, the air gap, and the second layer in sequence from the active region, wherein the second layer of the lower structure includes an upper surface in contact with the source/drain region, a side surface including at least a portion in contact with the active region, and a lower surface in contact with the first layer and capping the air gap, wherein the source/drain regions include a first semiconductor material having first impurities having a first conductivity type, and the second layer includes a second semiconductor material having no conductivity type or having second impurities of a second conductivity type different from the first conductivity type.

According to some example embodiments, a semiconductor device includes an active structure extending in a first direction and including a channel region and a recess region; a lower structure within the recess region; a source/drain region on the lower structure and including first impurities having a first conductivity type; and gate structures on both sides of the source/drain region taken in the first direction, intersecting the channel region, and extending in a second direction, wherein the lower structure includes a first layer in contact with the active structure and including an insulating material, a second layer on the first layer and including a semiconductor material, with an air gap interposed between the first layer and the second layer, wherein the semiconductor material of the second layer has no conductivity type or has impurities of a second conductivity type different from the first conductivity type.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to some example embodiments;

FIG. 2 is a cross-sectional diagram illustrating a semiconductor device according to some example embodiments;

FIG. 3 is an enlarged diagram illustrating a portion of a semiconductor device according to some example embodiments;

FIG. 4 is an enlarged diagram illustrating a portion of a semiconductor device according to some example embodiments;

FIG. 5 is an enlarged diagram illustrating a portion of a semiconductor device according to some example embodiments;

FIG. 6A is a cross-sectional diagram illustrating a semiconductor device according to some example embodiments;

FIG. 6B is an enlarged diagram illustrating a portion of a semiconductor device according to some example embodiments;

FIG. 7 is a cross-sectional diagram illustrating a semiconductor device according to some example embodiments; and

FIGS. 8A to 8J are cross-sectional diagrams illustrating processes of a method of manufacturing a semiconductor device in sequence according to some example embodiments.

### DETAILED DESCRIPTION

Hereinafter, various example embodiments will be described as follows with reference to the accompanying drawings.

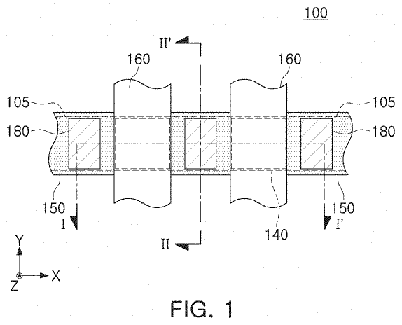

FIG. 1 is a plan diagram illustrating a semiconductor device according to some example embodiments.

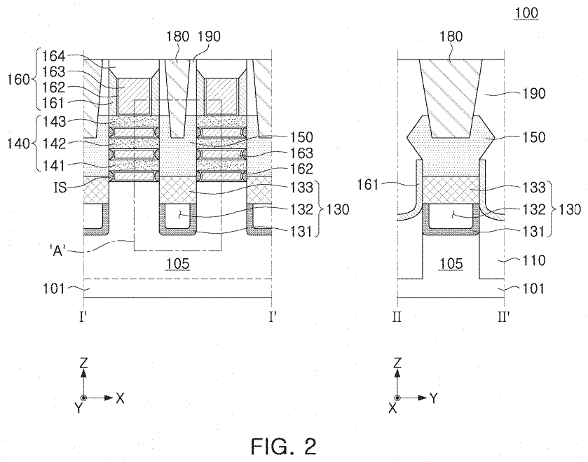

FIG. 2 is a cross-sectional diagram illustrating a semiconductor device according to some example embodiments, taken along lines I-I′ and II-II′ in FIG. 1.

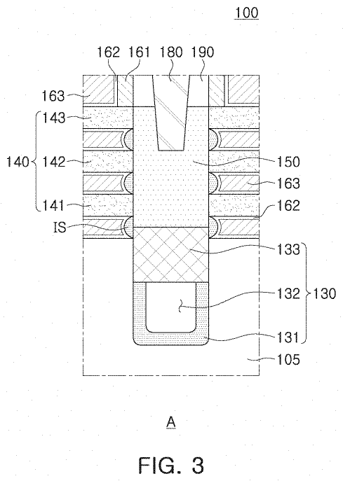

FIG. 3 is an enlarged diagram illustrating a portion of a semiconductor device according to some example embodiments, illustrating region “A” in FIG. 2.

For ease of description, only main components of the semiconductor device are illustrated in FIGS. 1 to 3.

Referring to FIGS. 1 to 3, a semiconductor device 100 may include a substrate 101, an active region 105 on the substrate 101, a lower structure 130 disposed in a recess region of the active region 105, a channel structure 140 including a plurality of channel layers 141, 142, 143 vertically disposed and spaced apart from each other on the active region 105, a source/drain region 150 in contact with the plurality of channel layers 141, 142, and 143 on the lower structure 130, a gate structure 160 extending by intersecting the active region 105, and a contact plug 180 connected to the source/drain region 150.

The semiconductor device 100 may further include device isolation layers 110 defining the active region 105. Additionally or alternatively, the semiconductor device 100 may further include an interlayer insulating layer 190 covering the active region 105, the channel structure 140, and the source/drain region 150. The gate structure 160 may include a spacer layer 161, a gate dielectric layer 162, a gate electrode layer 163, and a gate capping layer 164.

In the semiconductor device 100, the active region 105 may have a fin structure, and the gate electrode layer 163 may be disposed between the active region 105 and the channel structure 140, between the plurality of channel layers 141, 142, and 143 of the channel structures 140, and on the channel structure 140. Accordingly, the semiconductor device 100 may include a gate-all-around (GAA) type field effect transistor formed by the channel structure 140, the source/drain regions 150, and the gate structure 160. For example, the semiconductor device may include a multi bridge channel FET (MBCFET™). The transistor may be, for example, an NMOS or PMOS transistor.

The substrate 101 may have an upper surface extending in the X-direction and the Y-direction. The substrate 101 may include a semiconductor material, such as, for example, one or more of a group IV semiconductor, a group III-V compound semiconductor, or a group II-VI compound semiconductor. For example, the group IV semiconductor may include silicon (Si), germanium (Ge), or silicon-germanium (SiGe). The substrate 101 may be provided as or may have been a bulk wafer, an epitaxial layer, an epitaxial layer, a silicon on insulator (SOI) layer, a semiconductor on insulator (SeOI) layer, or the like. The semiconductor device 100 may have been formed on a wafer, and may later have been diced or singulated; example embodiments are not limited thereto.

The device isolation layer 110 may define an active region 105 in the substrate 101. The device isolation layer 110 may be formed by, for example, a shallow trench isolation (STI) process. In some example embodiments, the device isolation layer 110 may further include a region having a step difference and extending further deeply to a region below the substrate 101. The device isolation layer 110 may at least partially expose an upper portion of the active region 105. In some example embodiments, the device isolation layer 110 may have a curved upper surface having a higher level toward or above the active region 105. The device isolation layer 110 may be formed of an insulating material. The device isolation layer 110 may be, for example, oxide, nitride, or a combination thereof.

The active region 105 may be defined by the device isolation layer 110 in the substrate 101 and may be disposed to extend in the first direction X. The active region 105 may have a structure protruding from the substrate 101. An upper end of the active region 105 may be disposed to protrude by a particular level, such as a dynamically determined, or, alternatively a predetermined level from the upper surface of the device isolation layer 110. The active region 105 may be formed as a portion of the substrate 101, and/or may include an epitaxial layer grown from the substrate 101. The active region 105 on the substrate 101 may be partially recessed on both sides of the gate structure 160. At least a portion of the lower structure 130 may be disposed in the recess region of the active region 105. The active region 105 may include impurities or may include doped regions including impurities. The impurities may be one or more of boron, carbon, arsenic, or phosphorous; however, example embodiments are not limited thereto.

The lower structure 130 may be disposed to be in contact with the active region 105. At least a portion of the lower structure 130 may be disposed in the recess region of the active region 105. The lower structure 130 may include a first layer 131, an air gap 132, and a second layer 133 disposed in sequence from the active region 105. The air gap 132 may be defined by the first layer 131 and the second layer 133.

The first layer 131 may be disposed to be in contact with the active region 105 in a recess region of the active region 105. The first layer 131 may be disposed along a curve of the recess region of the active region 105. In some example embodiments, the first layer 131 may have a U-shape or an almost U-shape along the shapes of the active region 105 and the device isolation layer 110. For example, the first layer 131 may include a U-shaped internal surface, a U-shaped external surface, and an upper end connecting an internal surface to an external surface. The second layer 133 may be in contact with at least an upper end of the first layer 131, and be disposed on the first layer 131. The air gap 132 may be disposed on the U-shaped internal surface of the first layer 131.

However, the shape of the first layer 131 is not limited to the above examples. For example, the shape of the first layer 131 may vary depending on the shape of the recess region of the active region 105. Specifically, the downward curvature of the shape of the recess region of the active region 105 may change, and accordingly, the shape of the first layer 131 may change. Also, the upper end of the first layer 131 has a flat shape in FIGS. 2 and 3, but some example embodiments thereof is not limited thereto. In some example embodiments, the upper end of the first layer 131 may have an obliquely inclined plane, a curved surface, or the like.

The first layer 131 may be conformally disposed in the recess region of the active region 105, and may have a uniform thickness throughout the entire region. However, the thickness of the first layer 131 is not limited thereto. For example, the thickness of the upper portion of the first layer 131 may be less than the thickness of the lower portion. In some example embodiments, the thickness of the first layer 131 may gradually decrease toward the upper portion.

The second layer 133 may be disposed to be in contact with the first layer 131 on the first layer 131. The second layer 133 may include a lower surface in contact with the first layer 131, a side surface including at least a portion in contact with the active region 105, and an upper surface in contact with the source/drain region 150.

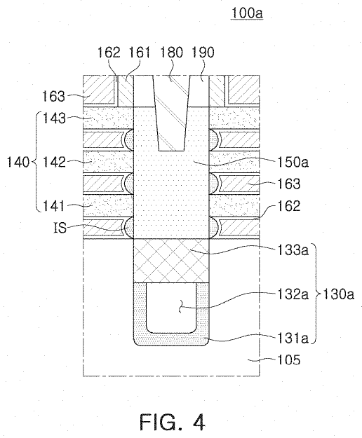

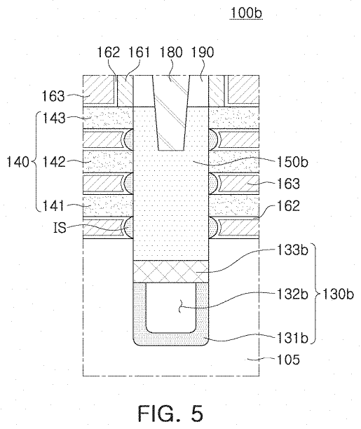

The upper surface of the second layer 133 may be disposed on a level below a level of the lower surface of the first channel layer 141. In some example embodiments, an upper surface of the second layer 133 may be disposed on a level higher than a level of an upper surface of the active region 105. However, the position of the upper surface of the second layer 133 is not limited thereto, and may be varied as in various example embodiments illustrated in FIGS. 4 and 5.

A portion of a side surface of the second layer 133 may be in contact with the active region 105. A remaining portion of a side surface of the second layer 133 may be in contact with the internal spacer layers IS. However, depending on the position of the lower structure 130, the entire side surface of the second layer may be in contact with only the active region 105 as in various example embodiments illustrated in FIGS. 4 and 5.

A lower surface of the second layer 133 may be disposed on a level below a level of an uppermost surface of the active region 105. A lower surface of the second layer 133 may be in contact with the first layer 131. The second layer 133 may cap an empty space formed by the internal surface of the first layer 131 and may define the air gap 132. For example the air gap 132 may be defined by the internal surface of the first layer 131 and the lower surface of the second layer 133 and may be interposed between the first layer 131 and the second layer 133. In FIGS. 2 and 3, the upper and lower surfaces of the second layer 133 has a flat shape, but some example embodiments thereof is not limited thereto, and the upper and lower surfaces of the second layer 133 may have a curved shape.

In some example embodiments, the air gap 132 may not include a solid material. In some example embodiments, the air gap 132 may include air, such as but not limited to clean, dry air (CDA). Alternatively or additionally, in some example embodiments, the air gap 132 may include a noble gas. The air gap 132 may be under vacuum; however, example embodiments are not limited thereto.

The first layer 131 may include an insulating material. For example, the first layer 131 may include silicon (Si), such as, for example, at least one of an insulating material among SiN, SiO, SiCN, SiOC, SiON, SiOCN, and SiBCN. The first layer 131 and the air gap 132 may reduce a leakage current from the source/drain region 150 to the active region 105.

The second layer 133 may include a semiconductor material. In some example embodiments, the second layer 133 may include a group IV semiconductor such as silicon (Si) or silicon-germanium (SiGe).

The semiconductor material of the second layer 133 may not have conductivity or may have conductivity type different from that of the source/drain region 150. That is, when the source/drain regions 150 are doped with first impurities of a first conductivity type, the second layer 133 may not have conductivity or may have a second conductivity type different from the first conductivity type. The second layer 133 may include no impurities or may include second impurities, e.g. impurities of a different conductivity type, different from the first impurities.

As described herein, a semiconductor material having a “conductivity type” may indicate that the semiconductor material includes impurities in such a concentration that the semiconductor may provide one of a majority of hole carriers, or a majority of electron carriers. A semiconductor material may have a first conductivity type, if the material has more impurities of a first conductivity type than impurities of a second conductivity type. Furthermore, a semiconductor material may have no impurities that are activated or included or incorporated therein, and may instead have a concentration of carriers that is intrinsic to the semiconductor material.

In some example embodiments, when the source/drain region 150 is doped with an n-type impurities (e.g., one or both of phosphorus (P) or arsenic (As)), the second layer 133 may not be doped with impurities, may include impurities such as carbon (C), nitrogen (N), and oxygen (O) such that the second layer 133 does not have conductivity, or the second layer 133 may be doped with p-type impurities (e.g., boron (B)) such that the second layer 133 has p-type conductivity and provides a majority of hole carriers. In some example embodiments, when the source/drain region 150 is doped with p-type impurities (e.g., boron (B)), the second layer 133 may not be doped with impurities, or may include impurities such as carbon (C), nitrogen (N), and oxygen (O) such that the second layer 133 does have conductivity, or the second layer 133 may be doped with n-type impurities (e.g., one or both of phosphorus (P) and arsenic (As)) such that the second layer 133 has n-type conductivity and provides a majority of electron carriers.

When the second layer 133 is doped with impurities, a concentration of the impurities may have a range of greater than 0 and about 1×10²⁰ at/cm³. For example, the concentration of impurities in the second layer 133 may be in a range of about 1×10¹⁷ at/cm³ to about 1×10²⁰ at/cm³. When the concentration of the impurities has the above range, a leakage current may be reduced, e.g. may be sufficiently reduced. A concentration of impurities may be determined by one or more of many methods, such as but not limited to secondary ion mass spectroscopy (SIMS), such as time-of-flight SIMS; however, example embodiments are not limited thereto.

The types of elements of the impurities included in the second layer 133 and the impurities included in the source/drain region 150 are not limited to any particular example. In some example embodiments, the first impurities and the second impurities may include one or more of arsenic (As), antimony (Sb), phosphorus (P), boron (B), gallium (Ga), carbon (C), oxygen (O), and nitrogen (N).

The lower structure 130 may reduce leakage current of the semiconductor device 100. The first layer 131 including an insulating material and the air gap 132 may reduce the possibility of leakage current from the source/drain region 150 to the active region 105, that is, a junction leakage current. The second layer 133 may reduce the possibility of a leakage current between the source/drain regions 150, for example, a punch-through phenomenon. For example, the lower structure 130 may prevent or reduce the amount of and/or the impact from a junction leakage current and/or a punch-through phenomenon of the semiconductor device 100, thereby improving electrical properties of the semiconductor device 100, and/or improving reliability.

Since the first layer 131 and the second layer 133 have different material compositions, the first layer 131, the air gap 132, and the second layer 133 may be distinct from each other by transmission electron microscopy energy-dispersive X-ray spectroscopy (TEM-EDS).

The channel structure 140 may include two or more channels such as the first to third channel layers 141, 142, and 143, two or more channel layers spaced apart from each other in a direction perpendicular to the upper surface of the substrate 101, for example, in a Z-direction. The first to third channel layers 141, 142, and 143 may be connected to the source/drain region 150 and may be spaced apart from the upper surface of the active region 105. The first to third channel layers 141, 142, and 143 may have a width the same as or similar to that of the active region 105 in the Y-direction, and may have a width the same as or similar to that the gate structure 160 in the X-direction. However, in some example embodiments, the first to third channel layers 141, 142, and 143 may have a reduced width such that side surfaces may be disposed below the gate structure 160 in the X-direction.

The first to third channel layers 141, 142, and 143 may be formed of a semiconductor material, and may include, for example, silicon (Si). The first to third channel layers 141, 142, and 143 may be formed of, for example, the same material as that of the substrate 101. The number of the channel layers 141, 142, and 143 and/or the shape of the channel layers 141, 142, and 143 included in the channel structure 140 may be varied in some example embodiments. For example, in some example embodiments, the channel structure 140 may further include a channel layer disposed on the upper surface of the active region 105.

The source/drain region 150 may be disposed to be in contact with the first to third channel layers 141, 142, and 143 on at least one side of the gate structure 160. The source/drain regions 150 may be disposed on the lower structure 130. For example, the source/drain regions 150 may be disposed to be in contact with the second layer 133 of the lower structure 130.

The source/drain region 150 may include a semiconductor material doped with impurities. In FIGS. 2 and 3, the source/drain region 150 is configured as a single layer, but some example embodiments thereof is not limited thereto. A plurality of layers of the source/drain regions 150 having different compositions may be stacked.

The upper surface of the source/drain region 150 may be disposed on a level the same as or similar to a level of the upper surface of the third channel layer 143, which is an uppermost channel layer, as illustrated in FIGS. 2 and 3. The relative levels of the source/drain region 150 and the channel structure 140 may be varied in some example embodiments. For example, the source/drain region 150 may have an elevated source/drain shape in which the upper surface is disposed on a level higher than a level of the upper surface of the third channel layer 143, which is the uppermost channel layer.

The gate structure 160 may intersect the active region 105 and the channel structures 140 above the active region 105 and the channel structures 140, and may extend in one direction, for example, a Y-direction. A channel region of transistors may be formed in the active region 105 and the channel structures 140 intersecting the gate structure 160. The gate structure 160 may include a gate electrode layer 163, a gate dielectric layer 162 disposed between the gate electrode layer 163 and the plurality of channel layers 141, 142, and 143, and spacer layers on side surfaces of the gate electrode layer 163. 161, and a gate capping layer 164 on the upper surface of the gate electrode layer 163.

The gate dielectric layer 162 may be disposed between the active region 105 and the gate electrode layer 163 and between the channel structure 140 and the gate electrode layer 163, and may cover at least a portion of the surfaces of the gate electrode layer 163. For example, the gate dielectric layer 162 may be disposed to surround entireties of surfaces other than the upper surface of the gate electrode layer 163. The gate dielectric layer 162 may extend to a region between the gate electrode layer 163 and the spacer layers 161, but some example embodiments thereof is not limited thereto. The gate dielectric layer 162 may include an oxide, nitride, or high-k dielectric material. The high-k dielectric material may refer to a dielectric material having a dielectric constant k greater than that of a silicon oxide layer (SiO₂). The high k dielectric constant material may be, for example, one or more of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The gate electrode layer 163 may fill a region between the plurality of channel layers 141, 142, and 143 and may extend to an upper portion of the channel structure 140 on the active region 105. The gate electrode layer 163 may be spaced apart from the plurality of channel layers 141, 142, and 143 by the gate dielectric layer 162. The gate electrode layer 163 may include a conductive material. For example, the gate electrode layer 163 may include at least one of a metal nitride (e.g., at least one of a titanium nitride film (TiN), a tantalum nitride film (TaN), and a tungsten nitride film (WN)), a metal material (e.g., aluminum (Al), tungsten (W), and molybdenum (Mo)) and silicon (e.g., doped polysilicon).

The gate electrode layer 163 may include two or more multiple layers. The spacer layers 161 may be disposed on both sides of the gate electrode layer 163. The gate spacer layers 161 may insulate the source/drain region 150 from the gate electrode layer 163. The spacer layers 161 may have a multilayer structure in some example embodiments. The spacer layers 161 may include at least one of an oxide, a nitride, an oxynitride, and a low-k dielectric.

The gate capping layer 164 may be disposed on the gate electrode layer 163, and a lower surface thereof may be surrounded by the gate electrode layer 163 and the spacer layers 161.

The internal spacer layers IS may be disposed in parallel with the gate electrode 165 between the channel structures 140. The internal spacer layers IS may be disposed on both sides of the gate structure 160 in the x direction on the lower surface of each of the first to third channel layers 141, 142, and 143. The gate electrode 165 may be spaced apart from the source/drain regions 150 by the internal spacer layers IS and may be electrically separated from the source/drain regions 150 below the first to third channel layers 141, 142, and 143.

One side surface of the internal spacer layers IS opposing the gate electrode 165 may be inwardly rounded toward the gate electrode 165. Another side surface or the other side surface of the internal spacers IS opposing the source/drain region 150 may be substantially coplanar with the first to third channel layers 141, 142, and 143. However, the shape of the internal spacers IS is not limited thereto.

The internal spacer layers IS may include an insulating material such as oxide, nitride, or oxynitride. In some example embodiments, the internal spacer layers IS may include the same material as that of the first layer 131 of the lower structure 130.

The contact plug 180 may penetrate the interlayer insulating layer 190 and may be connected to the source/drain region 150, and may apply an electrical signal to the source/drain region 150. The contact plug 180 may be disposed on the source/drain region 150, and may be disposed to have a length longer than that of the source/drain region 150 in the Y-direction in some example embodiments. The contact plug 180 may have an inclined side surface of which a width in a lower portion decreases further than a width in an upper portion depending on an aspect ratio, but some example embodiments thereof is not limited thereto. The contact plug 180 may be disposed to recess the source/drain region 150 by a predetermined depth. The contact plug 180 may include, for example, at least one of a metal nitride (e.g., at least one of a titanium nitride film (TiN), a tantalum nitride film (TaN), and a tungsten nitride film (WN)) and a metal material (e.g., aluminum (Al), tungsten (W) and molybdenum (Mo)).

The interlayer insulating layer 190 may be disposed to cover the source/drain region 150, the gate structure 160, and the device isolation layer 110. The interlayer insulating layer 190 may include, for example, at least one of an oxide, a nitride, an oxynitride, and a low-k dielectric.

FIG. 4 is an enlarged diagram illustrating a portion of a semiconductor device according to some example embodiments.

In various example embodiment in FIGS. 4 to 7, to describe some example embodiments different from various example embodiments in FIGS. 1 to 3, the elements may have the same reference numerals as those in FIGS. 1 to 3 but may spell differently. The same descriptions may be applied to the elements having the same reference numerals in the aforementioned example embodiment and in some example embodiments.

FIG. 4 is an enlarged diagram illustrating a portion of a semiconductor device 100a according to some example embodiments, illustrating a portion corresponding to region “A” in FIG. 2.

The semiconductor device 100a in FIG. 4 may be different from the semiconductor device 100 in FIGS. 1 to 3 in terms of the shapes of the lower structure 130a and/or the source/drain regions 150a.

Referring to FIG. 4, the entire lower structure 130a may be disposed in the recess region of the active region 105. The upper surface of the second layer 133a may be disposed on substantially the same level as a level of the upper surface of the active region 105. The entire side surface of the second layer 133a may be in contact with the active region 105 and may not be in contact with the internal spacer layers IS. The source/drain region 150a may extend to the level of the upper surface of the active region 105.

The shapes of the first layer 131a and the air gap 132a of the lower structure 130a in FIG. 4 may be the same as the example in the aforementioned example embodiment in FIGS. 1 to 3. The second layer 133a of the lower structure 130a in FIG. 4 may have a relatively small height as compared to some example embodiments in FIGS. 1 to 3. Accordingly, the upper surface of the second layer 133a of the lower structure 130a may be disposed on a level lower than in the aforementioned example embodiments. However, the shape of the components of the lower structure 130a is not limited thereto. In some example embodiments, the relative levels of the first layer 131a and the second layer 133a may change. For example, the first layer 131a may have a height smaller than that of the second layer 133a, and accordingly, the shape of the air gap 132a may change. In some example embodiments, the heights of the first layer 131a, the air gap 132a, and the second layer 133a may be maintained to be the same as in the aforementioned example embodiments in FIGS. 1 to 3, and the depth of the recess region of the active region 105 may increase.

FIG. 5 is an enlarged diagram illustrating a portion of a semiconductor device 100b according to some example embodiments, illustrating region “A” in FIG. 2.

The semiconductor device 100b in FIG. 5 may be different from the semiconductor device 100 in FIGS. 1 to 3 in terms of the shapes of the lower structure 130b and the source/drain regions 150b.

Referring to FIG. 5, the entire lower structure 130b may be disposed in the recess region of the active region 105. The upper surface of the second layer 133b may be disposed on a level lower than a level the upper surface of the active region 105. The entire side surface of the second layer 133b may be in contact with the active region 105 and may not be in contact with the internal spacer layers IS. The source/drain region 150b may extend to a level lower than a level of the upper surface of the active region 105.

As described above in some example embodiments in FIG. 4, the shapes of the first layer 131b, the air gap 132b, and the second layer 133b of the lower structure 130b are not limited to the examples illustrated in FIG. 5. The shape of each of the components included in the lower structure 130b may be configured differently in consideration of the size of the semiconductor device, leakage current, and the like.

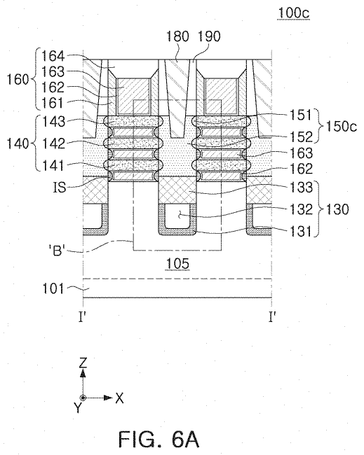

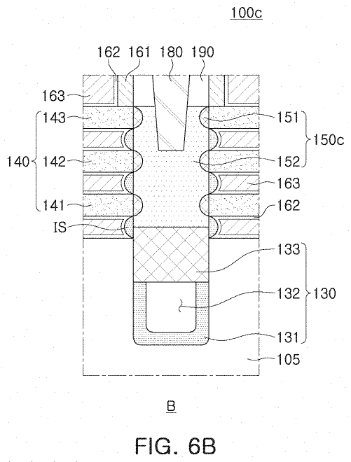

FIG. 6A is a cross-sectional diagram illustrating a semiconductor device 100c according to some example embodiments. FIG. 6B is an enlarged diagram illustrating a portion of a semiconductor device 100c according to some example embodiments, illustrating region “B” in FIG. 6A.

The semiconductor device 100c in FIGS. 6A and 6B may be different from the semiconductor device 100 in FIGS. 1 to 3 in terms of the structure of the source/drain region 150c.

Referring to FIGS. 6A and 6B, the source/drain region 150c may include a plurality of first patterns 151 and a second pattern 152. The first patterns 151 may be disposed on both side surfaces of the plurality of channel layers in the x direction. The first patterns 151 may be spaced apart from each other.

The first patterns 151 may include the same material as that of the second layer 133 of the lower structure 130. In some example embodiments, the first patterns 151 and the second layer 133 may include a semiconductor material having no conductivity type. For example, the first patterns 151 and the second layer 133 may include non-conductive silicon (Si) or silicon-germanium (SiGe). The first patterns 151 and the second layer 133 may not be doped with impurities or may not have conductivity by including impurities such as carbon (C), oxygen (O), and nitrogen (N). The size of the first patterns 151 may be varied, for example in consideration of one or more of the degree of addressing of a short channel effect, a magnitude of resistance, and the like.

The second pattern 152 may be disposed on the second layer 133 of the lower structure 130 and may be disposed to surround the plurality of first patterns 151. The second pattern 152 may include a semiconductor material doped with n-type or p-type impurities. For example, the second pattern 152 may be silicon (Si) or silicon-germanium (SiGe) doped with arsenic (As), antimony (Sb), phosphorus (P), boron (B), gallium (Ga), or the like.

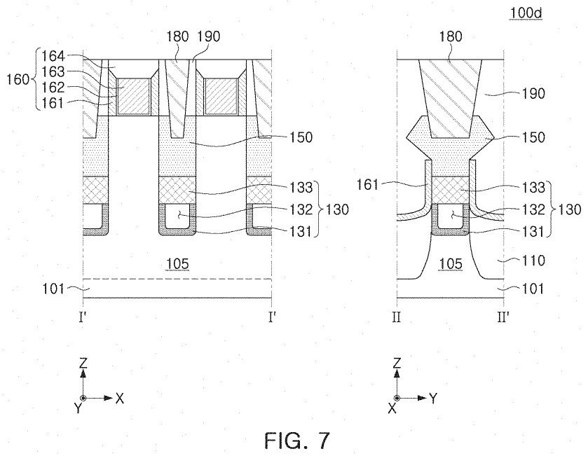

FIG. 7 is a cross-sectional diagram illustrating a semiconductor device 100d according to some example embodiments, illustrating regions corresponding to the cross-sections taken along lines I-I′ and II-II′ in FIG. 1. For ease of description, only main components of the semiconductor device are illustrated in FIG. 7. In FIG. 7, the same reference numerals as those in FIGS. 1 to 3 indicate corresponding elements.

Referring to FIG. 7, the semiconductor device 100d may include an active region 105, an isolation layer 110, a source/drain region 150, a gate structure 160, a contact plug 180, and an interlayer insulating layer 190. The semiconductor device 100d may include a FinFET device which may be a transistor having a fin structure in the active region 105. The FinFET device may be a transistor disposed around the active region 105 and the gate structure 160 intersecting with each other. For example, the FinFET device may be an NMOS or PMOS transistor.

The active structure may include an active region 105, a channel region and a recess region. Channel regions of transistors may be formed in the active region 105 intersecting the gate structures 160. The channel region may include a depletion region of transistors, and may refer to a region intersecting the gate structures 160 and adjacent to the gate structures 160 in the active region 105.

A lower structure 130 and a source/drain region 150 may be disposed in the recess region of the active region 105. The source/drain region 150 may include a first semiconductor material doped with or having first impurities of a first conductivity type. The second layer of the lower structure 130 may include a second semiconductor material having a second conductivity type different from the first conductivity type or having no conductivity type. The first layer of the lower structure 130 may include an insulating material.

The lower structure 130 disposed between the active region 105 and the source/drain region 150 may reduce leakage current of the semiconductor device 100d, thereby improving electrical properties of the semiconductor device 100d and improving reliability.

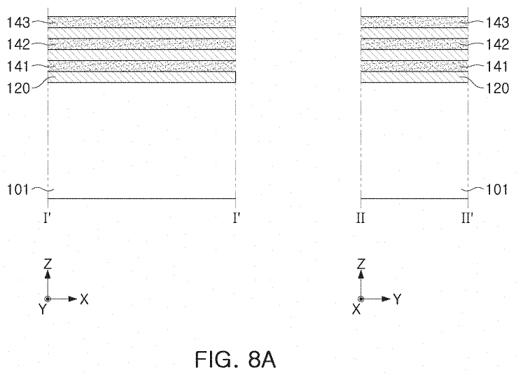

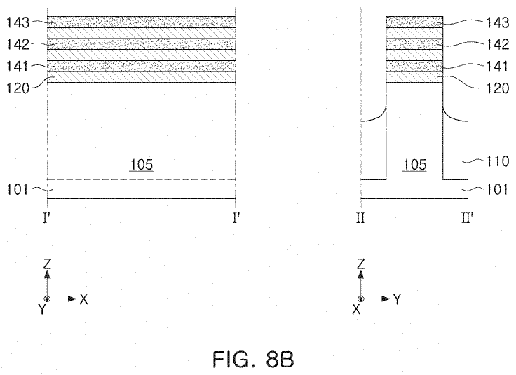

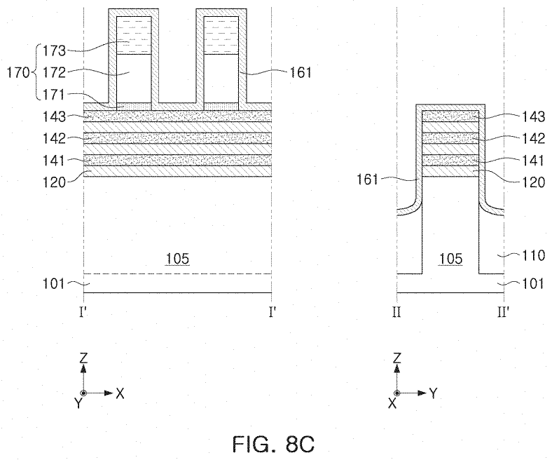

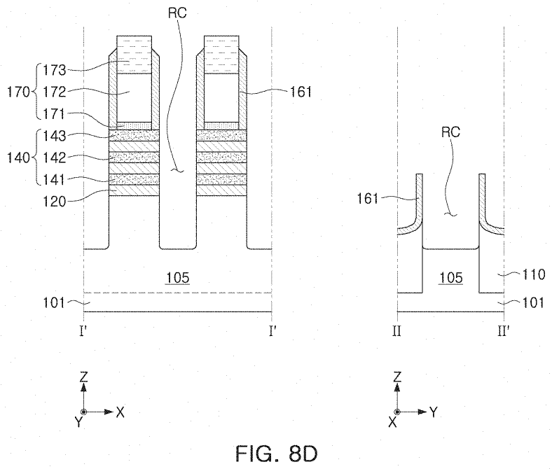

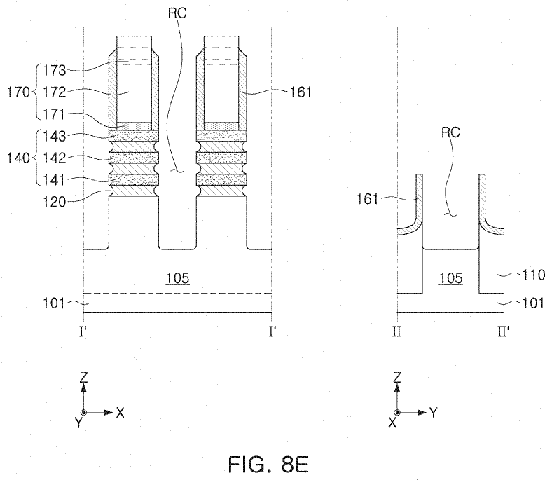

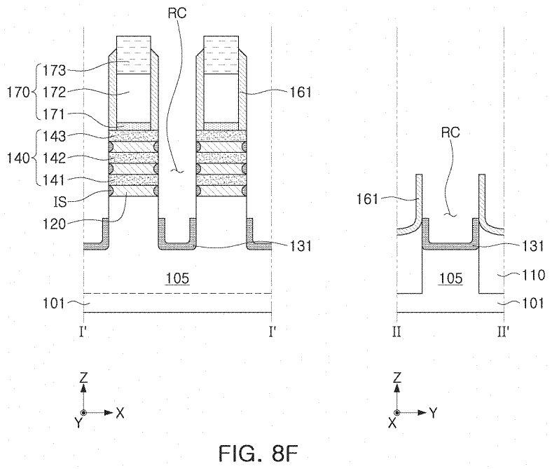

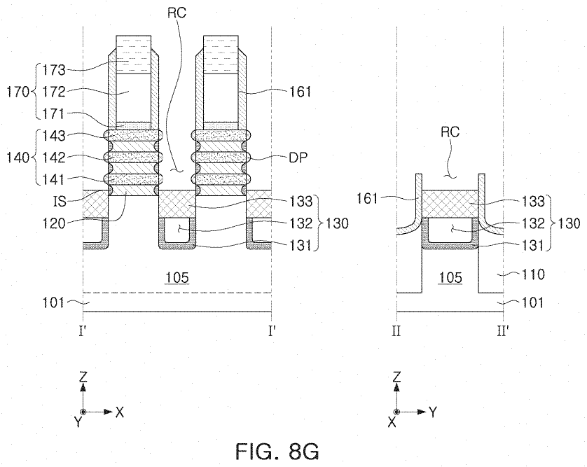

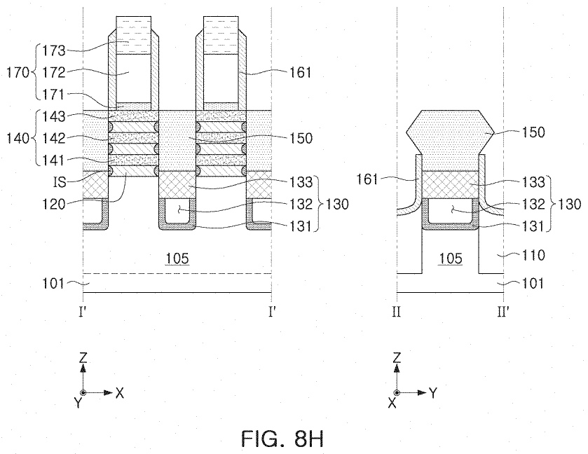

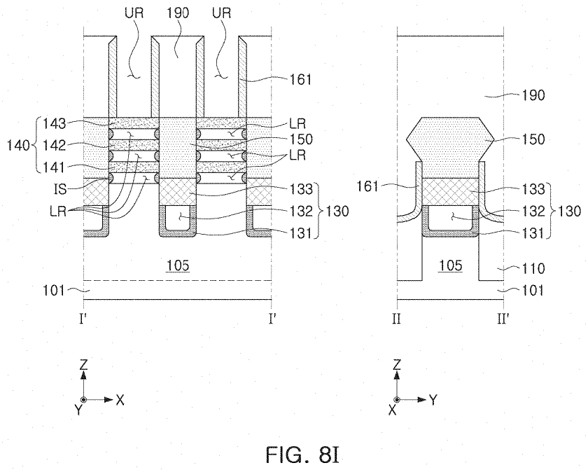

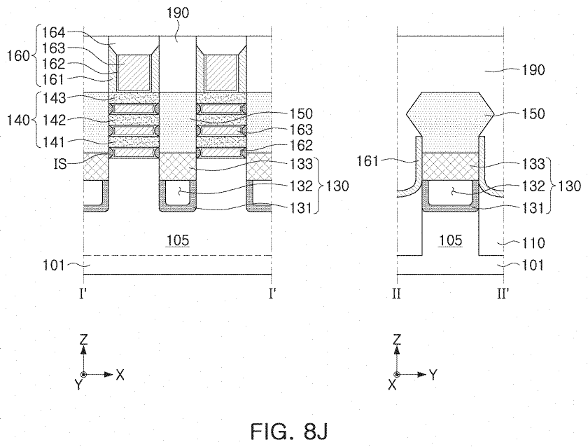

FIGS. 8A to 8J are cross-sectional diagram illustrating processes of a method of manufacturing a semiconductor device in sequence according to some example embodiments, illustrating some example embodiments of a method of manufacturing a semiconductor device illustrated in FIGS. 1 to 3, and illustrating cross-sections corresponding to FIG. 2.

Referring to FIG. 8A, sacrificial layers 120 and channel layers 141, 142, and 143 may be alternately stacked on a substrate 101.

The sacrificial layers 120 may be replaced with the gate dielectric layer 162 and the gate electrode layer 163 as illustrated in FIG. 2 through a subsequent process. The sacrificial layers 120 may be formed of a material having etch selectivity with respect to the channel layers 141, 142, and 143. The channel layers 141, 142, and 143 may include a material different from that of the sacrificial layers 120. In some example embodiments, the channel layers 141, 142, and 142 may include silicon (Si), and the sacrificial layers 120 may include silicon germanium (SiGe).

The sacrificial layers 120 and the channel layers 141, 142, and 143 may be formed by performing an epitaxial growth process using the substrate 101 as a seed. Each of the sacrificial layers 120 and the channel layers 141, 142, and 143 may have a thickness in a range of about 1 Å to 100 nm. The number of layers of the channel layers 141, 142, and 143 alternately stacked with the sacrificial layer 120 may be varied in some example embodiments.

Referring to FIG. 8B, active structures may be formed by removing the stack structure of the sacrificial layers 120 and the channel layers 141, 142, and 143 and a portion of the substrate 101.

The active structure may include sacrificial layers 120 and channel layers 141, 142, and 143 alternately stacked with each other, and may further include an active region 105 protruding to the upper surface of the substrate 101 by removing a portion of the substrate 101. The active structures may be formed in the form of lines extending in one direction, that is, for example, the X-direction, and may be spaced apart from each other in the Y-direction.

In the region from which a portion of the substrate 101 is removed, the device isolation layers 110 may be formed by filling an insulating material and recessing the active region 105 to protrude. An upper surface of the device isolation layers 110 may be disposed on a level lower than a level of an upper surface of the active region 105.

Referring to FIG. 8C, sacrificial gate structures 170 and spacer layers 161 may be formed on the active structures.

The sacrificial gate structures 170 may be sacrificial structures formed in a region on the channel structure 140 in which the gate dielectric layer 162 and the gate electrode layer 163 are disposed as illustrated in FIG. 2 through a subsequent process. The sacrificial gate structure 170 may include first and second sacrificial gate layers 171 and 172 and a mask pattern layer 173 stacked in sequence. The first and second sacrificial gate layers 171 and 172 may be patterned using the mask pattern layer 173. The first and second sacrificial gate layers 171 and 172 may be an insulating layer and a conductive layer, respectively. For example, the first sacrificial gate layer 171 may include silicon oxide, and the second sacrificial gate layer 172 may include polysilicon. The mask pattern layer 173 may include silicon nitride. The sacrificial gate structures 170 may have a linear shape intersecting the active structures and extending in one direction. The sacrificial gate structures 170 may extend, for example, in a Y-direction and may be spaced apart from each other in the X-direction.

The spacer layer 161 may cover the sacrificial gate structures 170 and the active structures. The spacer layer 161 may be formed as a film having a uniform thickness along upper surfaces and side surfaces of the sacrificial gate structures 170 and the active structures. The spacer layers 161 may be formed of a low-k material, and may include, for example, at least one of SiO, SiN, SiCN, SiOC, SiON, and SiOCN.

Referring to FIG. 8D, by forming a recess region RC by removing the exposed sacrificial layers 120 and the channel layers 141, 142, and 143 between the sacrificial gate structures 170, channel structures 140 may be formed.

The exposed sacrificial layers 120 and channel layers 141, 142, and 143 may be removed using the sacrificial gate structures 170 and the gate spacer layers 161 formed on the side surfaces of the sacrificial gate structures 170 as masks. Accordingly, the channel layers 141, 142, and 143 may have a limited length in the X-direction and may form the channel structure 140.

The spacer layer 161 covering the upper surfaces of the sacrificial gate structures 170 may be removed. Also, upper portions of the spacer layer 161 covering side surfaces of the sacrificial gate structures 170 may be removed. Accordingly, a plurality of spacer layers 161 may be formed and spaced apart from each other on both sidewalls of the sacrificial gate structures 170.

Referring to FIG. 8E, the exposed sacrificial layers 120 may be partially removed from the side surface.

The sacrificial layers 120 may be selectively etched with respect to the channel structures 140 by, for example, a wet etching process, and may be removed by a predetermined depth from the side surface in the x direction. The sacrificial layers 120 may have an inwardly curved side surface by etching the side surface. However, the shape of the side surfaces of the sacrificial layers 120 is not limited to the illustrated example.

Referring to FIG. 8F, the internal spacer layers IS may be formed in the region from which the sacrificial layers 120 are removed, and the first layer 131 may be formed, e.g. conformally formed, below the recess region RC.

An insulating material may be filled in the region from which the recess region RC and the sacrificial layers 120 are removed, and the insulating material deposited on an external side of the channel structures 140 is removed, thereby forming the internal spacer layers IS and the first layer 131. In addition to removing the insulating material deposited on an external side of the channel structures 140, a portion of the insulating material deposited on the surface of the active region 105 may be removed together. Accordingly, the first layer 131 may be disposed on a level lower than a level of the upper surface of the active region 105.

The first layer 131 and the internal spacer layers IS may be formed of the same insulating material, e.g. at the same time. The first layer 131 and the internal spacer layers IS may include, for example, at least one of SiN, SiO, SiCN, SiOC, SiON, SiOCN, and SiBCN. In some example embodiments, the first layer 131 and the internal spacer layers IS may be formed of the same material as that of the spacer layers 161, but some example embodiments thereof is not limited thereto.

Referring to FIG. 8G, the second layer 133 may be formed on the first layer 131, and preliminary patterns DP may be formed on side surfaces of the channel structures 140.

The second layer 133 and the preliminary patterns DP may be formed using, for example, a selective epitaxial growth (SEG) process. The second layer 133 may be formed by growing from the active region 105 using an SEG process. The preliminary patterns DP may be formed by growing from the first to third channel layers 141, 142, and 143 using an SEG process. The second layer 133 and the preliminary patterns DP may be formed of the same material.

In some example embodiments, the second layer 133 and the preliminary patterns DP may be doped with impurities by in-situ doping. Impurities included in the second layer 133 and the preliminary patterns DP may be different from impurities included in the source/drain regions 150 (in FIG. 2) in the final structure. For example, when the semiconductor device includes an NMOS transistor, the second layer 133 and the preliminary patterns DP may be doped with a p-type impurities. For example, when the semiconductor device includes a PMOS transistor, the second layer 133 and the preliminary patterns DP may be doped with n-type impurities.

In some example embodiments, the second layer 133 and the preliminary patterns DP may not have conductivity, and may include one or more of carbon (C), oxygen (O), nitrogen (N), or the like, and/or may not be doped with impurities. The second layer 133 and the preliminary patterns DP may be formed of, for example, silicon (Si).

Referring to FIG. 8H, the preliminary patterns DP (in FIG. 8G) in the recess region RE (in FIG. 8G) may be removed, and the source/drain region 150 may be formed.

The preliminary patterns DP (in FIG. 8G) formed on the side surfaces of the channel structures 140 may be selectively removed, and the second layer 133 may remain in the recess region RE (in FIG. 8G). Thereafter, a source/drain region 150 filling the recess region RE (in FIG. 8G) may be formed on the second layer 133. The source/drain region 150 may be formed from the second layer 133 and the channel structures 140 by SEG, and may be doped with impurities by in-situ doping.

In some example embodiments, the source/drain region 150 may be doped with impurities having conductivity type different from that of the impurities included in the second layer 133. For example, when the semiconductor device may include an NMOS transistor, the second layer 133 may be doped with p-type impurities, and the source/drain region 150 may be doped with n-type impurities. For example, when the semiconductor device includes a PMOS transistor, the second layer 133 may be doped with n-type impurities, and the source/drain region 150 may be doped with p-type impurities.

The source/drain region 150 may be doped with impurities during formation of the source/drain region 150, e.g. during growth of the source/drain region 150. Alternatively or additionally, the source/drain region 150 may be doped with impurities after formation, e.g., with an implantation process such as an ion implantation process. Alternatively or additionally, the second layer 133 may be doped with impurities during formation thereof and/or after formation thereof; example embodiments are not limited thereto.

In some example embodiments, an entirety or a portion of the preliminary patterns DP (in FIG. 8G) may remain in the recess region RE (in FIG. 8G), differently from the example illustrated in FIG. 8H. For example, when the preliminary patterns DP (in FIG. 8G) do not have conductivity or are formed of a semiconductor material not doped with impurities, an entirety or a portion of the preliminary patterns DP (in FIG. 8G) may remain in the recess region RE (in FIG. 8G). In this case, the semiconductor device 100c illustrated in FIGS. 6A and 6B may be manufactured, and the preliminary patterns DP (in FIG. 8G) may be included in a first pattern 151 (in FIGS. 6A and 6B). Since the first pattern 151 (in FIGS. 6A and 6B) does not have conductivity opposite to that of the second pattern 152 (in FIGS. 6A and 6B), the short channel effect may be reduced without interfering with the flow of current.

Referring to FIG. 8I, an interlayer insulating layer 190 may be formed between the sacrificial gate structures 170 adjacent to each other on the source/drain region 150, and the sacrificial layers 120 and the sacrificial gate structure 170 may be removed.

The interlayer insulating layer 190 may be formed by forming an insulating layer covering the sacrificial gate structures 170 and the source/drain regions 150 and performing a planarization process.

The sacrificial layers 120 and the sacrificial gate structures 170 may be selectively removed with respect to the spacer layers 161, the interlayer insulating layer 190, and the channel layers 141, 142, and 143. The upper gap regions UR may be formed by removing the sacrificial gate structures 170, and the lower gap regions LR may be formed by removing the sacrificial layers 120 exposed through the upper gap regions UR. For example, when the sacrificial layers 120 include silicon germanium (SiGe) and the channel layers 141, 142, and 143 include silicon (Si) and may or may not include germanium, the sacrificial layers 120 may be selectively removed by performing a wet etching process using peracetic acid as an etchant.

Referring to FIG. 8J, a gate structure 160 may be formed in the upper gap regions UR and the lower gap regions LR.

The gate dielectric layer 162 may conformally cover internal surfaces of the upper gap regions UR and the lower gap regions LR. The gate electrode layer 163 may completely fill the upper gap regions UR and the lower gap regions LR. The gate electrode layer 163 and the spacer layers 161 may be removed by a predetermined depth from an upper portion in the upper gap regions UR. A gate capping layer 164 may be formed in a region in the upper gap regions UR from which the gate electrode layer 163 and the spacer layers 161 are removed. Accordingly, the gate structure 160 including the gate dielectric layer 162, the gate electrode layer 163, the spacer layers 161, and the gate capping layer 164 may be formed.

Thereafter, referring to FIG. 2, a contact hole may be formed by patterning the interlayer insulating layer 190, and a conductive material may be filled in the contact hole, thereby forming the contact plug 180.

A lower surface of the contact hole may be recessed into the source/drain regions 150, and the contact plug 180 may be formed to penetrate a portion of the source/drain region 150. However, the shape and arrangement of the contact plug 180 are not limited thereto, and may be varied.

According to various example embodiments, by disposing a lower structure for reducing leakage current below the source/drain region, a semiconductor device having improved electrical properties may be provided.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While various example embodiments have been illustrated and described above, it will be configured as apparent to those of ordinary skill in the art that modifications and variations could be made without departing from the scope as defined by the appended claims. Furthermore example embodiments are not necessarily mutually exclusive. For example, some example embodiments may include one or more features described with reference to one or more figures, and may also include one or more features described with reference to one or more other figures.

What is claimed is:

1. A semiconductor device, comprising:
an active region on a substrate and extending in a first direction;
a plurality of channel layers vertically spaced apart from each other on the active region;
a gate structure intersecting the active region and the plurality of channel layers, extending on the substrate in a second direction, and surrounding the plurality of channel layers;
a source/drain region contacting the plurality of channel layers on at least one side of the gate structure and including a first semiconductor material having first impurities of a first conductivity type; and
a lower structure in contact with the active region and below the source/drain region,
wherein the lower structure includes,
a first layer on the active region and including an insulating material, and
a second layer on the first layer and including a second semiconductor material,
the first layer and the second layer defining an air gap,
wherein the second semiconductor material of the second layer does not have impurities of a conductivity type or has impurities of a second conductivity type different from the first conductivity type.

2. The semiconductor device of claim 1,
wherein the first semiconductor material includes the first impurities in a first concentration, and
the second semiconductor material includes second impurities different from the first impurities in a second concentration that is less than the first concentration.

3. The semiconductor device of claim 2, wherein the second concentration is greater than or equal to 1×10¹⁷ at/cm³ and less than or equal to 1×10²⁰ at/cm³.

4. The semiconductor device of claim 1, wherein the source/drain region includes a plurality of first patterns on both sides of the plurality of channel layers taken in the first direction and spaced apart from each other, and the source/drain region includes a second pattern surrounding the plurality of first patterns on the second layer.

5. The semiconductor device of claim 4,
wherein the second semiconductor material of the second layer has no conductivity type,
the plurality of first patterns include a same material as the second semiconductor material, and
the second pattern includes the first semiconductor material.

6. The semiconductor device of claim 1, further comprising:
internal spacer layers on both sides of the gate structure taken in the first direction on a lower surface of each of the plurality of channel layers,
wherein the internal spacer layers include a same material as the insulating material of the first layer.

7. The semiconductor device of claim 1, wherein the insulating material included in the first layer includes at least one of SiN, SiO, SiCN, SiOC, SiON, SiOCN, and SiBCN.

8. The semiconductor device of claim 1, wherein each of the first semiconductor material and the second semiconductor material independently includes at least one of arsenic (As), antimony (Sb), phosphorus (P), boron (B), gallium (Ga), carbon (C), oxygen (O), and nitrogen (N).

9. A semiconductor device, comprising:
an active region extending on a substrate in a first direction;
a plurality of channel layers vertically spaced apart from each other on the active region;
a gate structure on the substrate, intersecting the active region and the plurality of channel layers, extending in a second direction, and surrounding the plurality of channel layers;
a source/drain region contacting the plurality of channel layers on at least one side of the gate structure; and
a lower structure in contact with the active region, below the source/drain region, and including a first layer, and a second layer with an air gap between the first layer and the second layer, the first layer, the air gap, and the second layer in sequence from the active region,
wherein the second layer of the lower structure includes,
an upper surface in contact with the source/drain region,
a side surface including at least a portion in contact with the active region, and
a lower surface in contact with the first layer and capping the air gap,
wherein the source/drain regions include a first semiconductor material including first impurities having a first conductivity type, and
the second layer includes a second semiconductor material having no conductivity type or having impurities of a second conductivity type different from the first conductivity type.

10. The semiconductor device of claim 9, wherein the upper surface of the second layer is on a level below a level of a lower surface of a lowermost channel layer among the plurality of channel layers.

11. The semiconductor device of claim 10, wherein the upper surface of the second layer is on a level between the lower surface of the lowermost channel layer among the plurality of channel layers and an uppermost surface of the active region.

12. The semiconductor device of claim 9, wherein
the active region includes a recess region, and
at least a portion of the lower structure is within the recess region.

13. The semiconductor device of claim 9, wherein the lower surface of the second layer is on a level below a level of an uppermost surface of the active region.

14. The semiconductor device of claim 9, further comprising:
a plurality of internal spacer layers on both sides of the gate structure taken in the first direction on a lower surface of each of the plurality of channel layers.

15. The semiconductor device of claim 14, wherein the side surface of the second layer includes a portion in contact with a portion of the plurality of internal spacer layers.

16. The semiconductor device of claim 9, wherein the source/drain region includes a plurality of first patterns covering both side surfaces of the plurality of channel layers taken in the first direction, and the source/drain region includes a second pattern on the second layer and surrounding the plurality of first patterns.

17. The semiconductor device of claim 16, wherein the plurality of first patterns are spaced apart from each other in a direction perpendicular to an upper surface of the substrate.

18. The semiconductor device of claim 16, wherein
the second semiconductor material of the second layer has no conductivity type,
the plurality of first patterns includes a same material as the second semiconductor material, and
the second pattern includes the first semiconductor material.

19. A semiconductor device, comprising:
an active structure extending in a first direction and including a channel region and a recess region;
a lower structure within the recess region;
a source/drain region on the lower structure and doped with first impurities having a first conductivity type; and
gate structures on both sides of the source/drain region taken in the first direction, intersecting the channel region, and extending in a second direction,
wherein the lower structure includes,
a first layer in contact with the active structure and including an insulating material, and
a second layer disposed on the first layer and including a semiconductor material, and
with an air gap interposed between the first layer and the second layer,
wherein the semiconductor material of the second layer has no conductivity type or has impurities of a second conductivity type different from the first conductivity type.

20. The semiconductor device of claim 19, wherein the second layer includes second impurities different from the first impurities in a concentration of greater than or equal to 1×10¹⁷ at/cm³ and less than or equal to 1×10²⁰ at/cm³.
